(19) United States
(12) Patent Application Publication
(10) Pub. No.: US 2026/0312557 A1
(43) Pub. Date: Oct. 8, 2026

(54) TRANSIMPEDANCE AMPLIFIER WITH AUTOMATIC GAIN CONTROL FOR SIGNAL ACQUISITION

(71) Applicant: Technion Research & Development Foundation Limited, Haifa (IL)

(72) Inventors: Shahar KVATINSKY, Haifa (IL); Sariel HODISAN, Haifa (IL)

(73) Assignee: Technion Research & Development Foundation Limited, Haifa (IL)

(21) Appl. No.: 19/479,442

(22) PCT Filed: Apr. 28, 2024
(86) PCT No.: PCT/IL2024/050408

§ 371 Date: Oct. 28, 2025

Related U.S. Application Data
(60) Provisional application No. 63/462,539, filed on Apr. 28, 2023.

(51) Int. Cl. H03F 3/45

(52) U.S. Cl. CPC H03F 3/45475; H03F 2203/45524

(57) ABSTRACT

A device for signal acquisition, comprises a transimpedance amplifier having an input receiving a current from an input device, an output to supply an output voltage reflective of the current; and a memristor component connected in a feedback path of the transimpedance amplifier, the memristor component transitioning between a high resistive state and a low resistive state depending on a voltage difference across the memristor component. The gain of the transimpedance amplifier is reduced as the increase in current approaches a saturation level of the amplifier and triggers the transition. The result is an increase in dynamic range of the transimpedance amplifier to better match the range of current output that may be expected from say an optical input device.

### RELATED APPLICATIONS

This application claims the benefit of priority of U.S. Provisional Patent Application No. 63/462,539 filed on Apr. 28, 2023, the contents of which are incorporated herein by reference in their entirety.

### FIELD AND BACKGROUND OF THE INVENTION

The present invention, in some embodiments thereof, relates to a transimpedance amplifier with automatic gain control for signal acquisition and, more particularly, but not exclusively, to a transimpedance amplifier where a wider dynamic range is sought, for example for the kind of signal range found in optical input devices.

Transimpedance amplifiers (TIAs) are used in many optical and radio-frequency (RF) systems for communication, measurement, and bio-sensing applications. The TIA, often constructed from one or two operational amplifiers converts an input current to an output voltage, the output voltage typically being amplified. Thus TIAs may be used to convert the input current from a photo-diode or a previous Gₘ stage into an amplified voltage signal. Since TIAs are the first (or one of the first) circuit blocks in receiving and sensing electronics circuits, they are expected to provide high gain and low noise. By that, they can overcome the noise of the succeeding stages and maximize the total circuit signal-to-noise ratio (SNR) and sensitivity. Designing a high dynamic range TIA for optical sensing applications is challenging since the photo-diode current itself has a high dynamic range that needs to be fully covered if the TIA is to be effective. Injecting a high input current into the TIA stage can easily saturate the TIA, and cause it to be insensitive to input signals for a while, leading in effect to blind time for the receiver circuit. Overcoming this limitation requires installing an automatic gain control (AGC) amplifier or other advanced techniques to create a wide dynamic range TIA that can withstand high input currents before being saturated.

Overcoming the above limitation may require installing an automatic gain control (AGC) amplifier or equivalent techniques to create a wide dynamic range TIA that can better withstand high input currents before being saturated, however current forms of AGC are too slow to avoid saturation when the source current changes quickly. Current forms of AGC may also require complex circuitry that requires higher power consumption and takes up valuable area on a circuit board or integrated circuit.

### SUMMARY OF THE INVENTION

The present embodiments use a memristor-based component for biasing in the automatic gain control (AGC). The memristor-based component, for example resistive random access memory (ReRAM), itself changes its resistance and thus provides a faster reaction from the AGC.

According to an aspect of some embodiments of the present invention there is provided a device for signal acquisition, comprising:
a transimpedance amplifier having at least one input, the at least one input being connected to receive a current from an input device;
an output of the transimpedance amplifier configured to supply an output voltage in response to the current; and
a memristor component connected in a feedback path of the transimpedance amplifier, the feedback path being between the output and the at least one input, the memristor component being configured to transition between a high resistive state and a low resistive state depending on a voltage difference across the memristor component, thereby to reduce a gain of the transimpedance amplifier following an increase in the current, thereby to increase a dynamic range of the transimpedance amplifier.

In embodiments, the memristor component is a resistive random access memory (ReRAM) component.

In embodiments, the memristor component is a valence change mechanism (VCM) ReRAM device.

In embodiments, the memristor component is a volatile memristor, for example a Mott volatile memristor device.

In embodiments, the dynamic range is configured to maintain responsiveness of the transimpedance amplifier to an expected current range of the input device.

In embodiments, the memristor component has a predetermined

$$\frac{{R}_{off}}{{R}_{on}}$$

ratio and the bandwidth is increased by the predetermined

$$\frac{{R}_{off}}{{R}_{on}}$$

ratio.

In embodiments, the memristor component is selected for a set transition in an order of magnitude of nanoseconds.

Embodiments may comprise a measurement component for measuring the output voltage, and using the measurement to supply a reset signal to the memristor component. The measurement component may not be needed in the case of the volatile memristor since the volatile memristor may be self-resetting.

In embodiments, a diplexer may be connected to split the output voltage into a first signal path indicative of the input current and a second signal path indicative of a need to reset the memristor component, the measurement device being connected to the second signal path. Again the diplexer may be dispensed with in the case of the volatile memristor.

In embodiments, the transimpedance amplifier comprises an inverting input and a non-inverting input, the non-inverting input being connected to a sinusoidal source, to be amplified by the transimpedance amplifier to indicate gain, the first signal path being low pass filtered and the second signal path being high pass filtered.

The device may be implemented as an integrated circuit, or may use discrete components.

According to a second aspect of the present invention there is provided a method of signal acquisition from an input device using a transimpedance amplifier comprising:
obtaining a current from the input device, the current being within a current range of the input device;
amplifying the current using the transimpedance amplifier;
controlling a gain of the transimpedance amplifier by connecting a memristor component across a feedback path of the transimpedance amplifier, the memristor component selected to have a set transition close to a saturation level of the transimpedance amplifier, thereby to decrease a gain of the transimpedance amplifier prior to the current reaching the saturation level and thereby to increase a dynamic range of the transimpedance amplifier to better match the current range of the input device.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

### BRIEF DESCRIPTION OF THE SEVERAL VIEWS OF THE DRAWING(S)

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 is a simplified diagram showing an embodiment of the present invention using a non-volatile memristor as a gain control component for a transimpedance amplifier;

FIG. 2 is a simplified diagram of a transimpedance amplifier using gain set by a resistor according to the prior art;

FIG. 3a to 3d are graphs showing the characteristics of a device according to FIG. 2 and showing how the device enters saturation for a certain amount of time;

FIG. 4(a) is a a cross-sectional diagram of the layers of a VCM memristor, and FIG. 4(b) is a microscope image of a pair of VCM memristors;

FIG. 5 is a plot of the measured current voltage IV characteristic of the VCM memristor of FIG. 4;

FIGS. 6(a) to 6(d) are views of successive stages of construction of a device according to the present embodiments as discrete components on a PCB board;

FIG. 7 is a generalized circuit diagram of a device according to the present embodiments using a non-volatile memristor;

FIGS. 8(a) and 8(b) are two diagrams illustrating the device of FIG. 1 and the two output voltages for the different memristor states respectively;

FIG. 9 is a simplified graph showing waveforms at different nodes of the device of FIG. 7 and illustrating the memristor transition and its effect according to embodiments of the present invention;

FIG. 10(a) and 10(b) are top and bottom views respectively of a discrete component implementation of the device of FIG. 7;

FIG. 11 is a frequency against gain characteristic for a TIA controlled by a memristor according to the present embodiments;

FIG. 12 is graph showing waveforms when a memristor starting in HRS state is switched to LRS and the corresponding reduction of the TIA gain, according to embodiments of the present invention;

FIG. 13 is a graph showing the waveforms associated with the reset signal when the memristor is switched back from LRS state to HRS state according to embodiments of the present invention; and

FIG. 14 is a flow chart showing the operation of a device according to embodiments of the present invention.

### DESCRIPTION OF SPECIFIC EMBODIMENTS OF THE INVENTION

The present invention, in some embodiments thereof, relates to a transimpedance amplifier with automatic gain control for signal acquisition and, more particularly, but not exclusively, to a transimpedance amplifier that is provided with a dynamic range commensurate with the dynamic range of an input current that may be expected from say an optical source, thus avoiding or reducing blind time.

A device for signal acquisition, comprises a transimpedance amplifier having an input receiving a current from an input device, an output to supply an output voltage reflective of the current; and a memristor component connected in a feedback path of the transimpedance amplifier, the memristor component transitioning between a high resistive state and a low resistive state depending on a voltage difference across the memristor component. The gain of the transimpedance amplifier is reduced as the increase in current approaches a saturation level of the amplifier and triggers the transition. The result is an increase in dynamic range of the transimpedance amplifier to better match the range of current output that may be expected from say an optical device.

In discrete implementations of the device the transimpedance amplifier may have separate inverting and non-inverting inputs, and the signal from the input device may be connected to the inverting input. In integrated circuit implementations there is often less distinction between inverting and non-inverting inputs.

In greater detail, the present embodiments may provide a design for an AGC mechanism for the TIA based on emerging memristor technology. Embodiments may use resistive random access memory (ReRAM) as the memristive technology. ReRAM performs resistive switching between a high resistance state (HRS) and a low resistance state (LRS). Applying an external short voltage pulse across the ReRAM memristor device activates the transition of the device from one resistive state to the other. Since both these states retain their values after the applied voltage is removed, ReRAM can conveniently be used as a non-volatile memory device. ReRAM memristors exhibit a gradual RESET transition, that is the LRS to HRS transition, and abrupt SET transition, that is the transition from HRS to LRS. This feature makes them eminently suitable for high-speed switching to a lower resistance once the voltage applied to them reaches a threshold voltage. The present embodiments may focus on the valence-change mechanism (VCM) ReRAM memristor because of its abrupt switching to an LRS, high endurance, and moderate threshold voltages.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

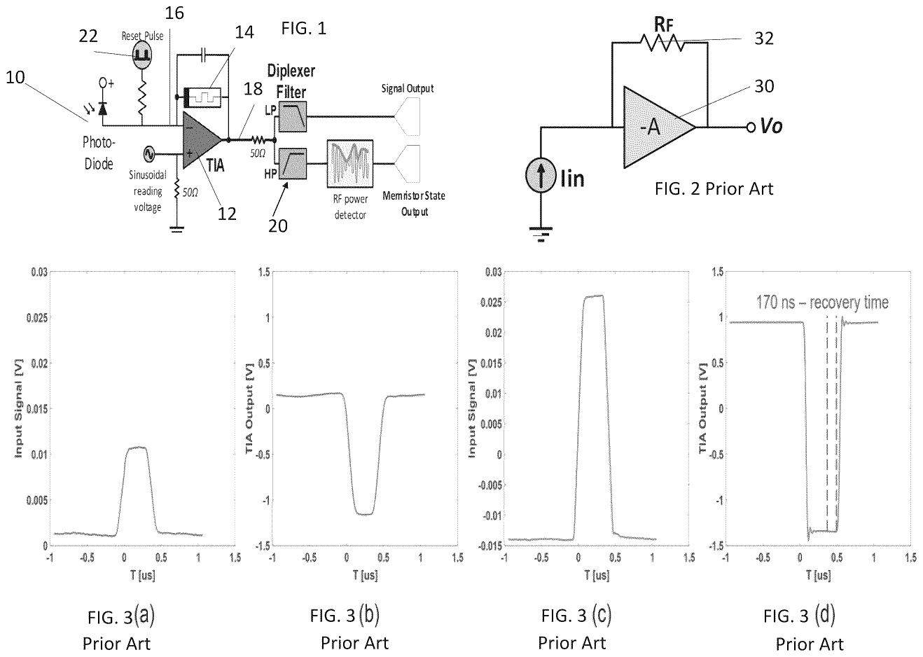

Referring now to the drawings, FIG. 1 illustrates circuitry according to a first embodiment of the present invention for a memristor-based transimpedance amplifier with automatic gain control (AGC). A photo-diode 10 is connected to a TIA based on an operational amplifier 12. A memristor 14 is placed in the operational amplifier feedback path to provide the TIA with AGC capability. The memristor device 14 may increase the TIA stage dynamic range by changing between two states as will be explained now in greater detail. The incorporated memristor 10 grants the TIA AGC capability. The memristor 10 is located in the operational amplifier's feedback path between the inverting terminal 16 and the output 18, where it is able to set the TIA's gain. Since its resistance can be switched when the current through the memristor varies—and accordingly, there is a voltage drop across the memristor, the memristor is used to provide ACG capabilities to the TIA. The memristor may thus switch the gain of the TIA between Roff and Ron. The gain diminution happens automatically and very fast as the current through the TIA stage increases and passes a certain threshold before the TIA saturates. The present method thus extends the TIA's dynamic range in line with the memristor's Roff/Ron ratio.

The present embodiments may further include a reading circuit 20 that monitors the memristor state. Once the TIA gain is to be changed back to high impedance, to allow it to receive low amplitude currents, the present solution allows a reset pulse 22 to be applied to the operational amplifier input to restore the memristor to a high resistance state.

In the following, we first confirm the validity of our proposed circuit using SPICE simulations. The, we experimentally demonstrate a solution according to the present embodiments using a full board containing the TIA stage, a memristor, and auxiliary circuits and evaluate its operation using electronic test equipment. Our experimental results show good agreement with the circuit behavior seen in simulations. The measurements confirm that the present solution enables the ex-tension of the TIA's dynamic range by the memristor's Roff ratio automatically, according to the input current signal level. For the memristor device used, the dynamic range can be extended by approximately 40 dB compared to resistor-based TIAs.

The organization of the sections following begins by presenting the operation of high dynamic range TIA based on operational amplifiers. Then, we detail the information regarding the used VCM memristor. This is followed by a detailed explanation of the proposed circuit. SPICE simulations of the proposed circuit are then presented, and then a prototype on a manufactured board with its measured performance is shown, followed by a conclusion.

### High Dynamic Range Transimpedance Amplifiers

Transimpedance amplifiers are usually based on operational amplifiers with a feedback network. The block diagram of a basic TIA is shown in FIG. 2. A resistor R_{F} 30 is placed in a negative feedback loop around an amplifier 32 having an open loop gain A. The transimpedance gain of such a circuit is

$${R}_{T} = \frac{- A \cdot {R}_{F}}{1 + A}$$

As long as the open-loop gain of the amplifier is sufficiently high, the transimpedance gain of this circuit would be approximately—R_{F}. This circuit also possesses a low input impedance given by

$${R}_{in} = \frac{{R}_{F}}{1 + A}$$

and, therefore, it is an ideal circuit to connect directly to a current source. Hence, TIA circuits are used in many optical circuits (for communication or measurements) as the amplifying stage after the photo-diode, allowing conversion of the input current (as produced by the photo-diode) to voltage while also furnishing enough gain to overcome the noise of the following stages, thereby improving the SNR (signal-to-noise ratio) of the whole circuit.

TIA is also used as a following stage for Gₘ stages in current-mode RF front-end circuits. This reduces the voltage swings compared to voltage-mode RF front-end circuits, which improves the circuit linearity when there are blocker signals. The feedback resistor also sets the 3 dB bandwidth of the TIA, which is

$${BW}_{3 dB} = \frac{A + 1}{2 π {R}_{F} {C}_{T}} \qquad ( 1 )$$

where C_{T} is the total capacitance at the input of the amplifier (mostly due to the photo-diode capacitance). Usually, a feed-back capacitor, C_{F}, is connected in parallel to the resistor R_{F} to limit the amplifier bandwidth and improve stability. When a feedback capacitor is added, the 3 dB bandwidth of the TIA is limited and becomes

$${BW}_{3 dB} < \frac{\sqrt{\frac{1}{2}}}{2 π {R}_{F} {C}_{F}} \qquad ( 2 )$$

From (1), the feedback resistor R_{F} controls the TIA gain and the 3 dB bandwidth. It also controls the TIA's dynamic range. The TIA's dynamic range can be defined qualitatively as

$$Dynamic range = ( Maximum input current ) / ( Input current noise ) \qquad ( 3 )$$

The feedback resistance, R_{F}, is one of the noise sources of the TIA stage, but it also determines the TIA input-referred noise quantitatively according to

$$Input current noise = ( TIA output voltage noise ) / {R}_{F} . \qquad ( 4 )$$

Using a high feedback resistor value (R_{F}) is beneficial to decrease the input-referred current noise. However, A high feedback resistor value can limit the maximum input current that the TIA stage can amplify, as the amplifier's output volt-age is limited by its supply voltage. The larger the feedback resistor value is, the lower the maximum input current the TIA can amplify, and

$$Max input current = ( Maximum output voltage ) / {R}_{F} \qquad ( 5 )$$

From (3)-(5), the feedback resistor value must be carefully selected to maximize the TIA's dynamic range. Furthermore, since the feedback resistor, R_{F}, also sets the TIA stage gain and bandwidth, the TIA's gain trades off the bandwidth and dynamic range. When the input current is higher than the maximum current, the TIA stage cannot amplify the input signal. The amplifier saturates and becomes insensitive to input signals for an indefinite period of time. This saturation is demonstrated in FIGS. 3a-3d which show input v output for a TIA according to the prior art, herein the TIA is based on the LMH6601 amplifier before and after saturation. FIG. 3 (a) shows a small non-saturating input signal, and FIG. 3(b) shows the corresponding TIA output. FIG. 3(c) shows a high input signal that saturates the TIA and FIG. 3(d) shows the saturated TIA output with a 170 ns recovery time. There is thus a considerable time delay until the TIA recovers and can respond to the input signal.

Several methods have been proposed to untangle the above tradeoffs and increase the TIA dynamic range. One method is to divide the TIA gain between two or more stages and have the subsequent stages be voltage amplifiers. This method allows the TIA to have a lower feedback resistance value (gain) and become saturated for higher input currents. Furthermore, it increases the total noise, power, and area of the whole circuit. Another method uses a nonlinear feedback network containing a diode or a transistor to implement a logarithmic TIA. Such a TIA can operate over several decades of input current, substantially increasing the TIA's input overload current. The drawbacks of this method are increased noise, amplifier instability, and nonlinearity for large signals. The dynamic range can also be increased by reducing the noise of the TIA stage. This allows the TIA to have a lower gain (lower feedback resistor value) as less gain is needed to overcome the noise of the following stages. TIA noise can be reduced by using lower noise amplifiers (improved transistors process technology) or by lowering the TIA input capacitance using a common-base (or gate) stage before the TIA. Such a method requires a delicate design as the common-base stage contributes to the total noise of the circuit and can cancel out the reduction in TIA noise. Another solution when the dynamic range of the photodiode is very high, and high input currents are to be expected, is to split the high current input among several parallel TIA stages. The drawback of this method would be the extra power and area used for the design.

Another popular way to increase the TIA dynamic range is using an automatic gain control (AGC) mechanism. An AGC is a control loop that measures the output voltage of the TIA. Accordingly, it controls the TIA gain by fine-tuning (or switching) its feedback resistor or a variable input current attenuator. Several commercial TIA devices using programmable gain are available. The drawbacks of this method are the extra circuit complexity needed for the control loop, the need to assure stability for all TIA possible gain values, and the non-instantaneous gain switching (or tuning) time.

The present embodiments, by contrast, propose a TIA with an AGC mechanism based on a memristor device to eliminate the above-discussed problems.

### ReRAM VCM

Resistive switching devices (ReRAMs) are among the most common memristor technologies. The resistive switching of ReRAM devices is based on the growth of a conductive filament inside the device's dielectric due to the application of an external voltage. When the filament connects the top and bottom electrodes of the device, a low resistance state (LRS) is obtained. Once an inverse voltage (for a bipolar switching device) is applied across the device, the conducting filament is ruptured, and the device switches to a high resistance state (HRS). Depending on the material composition of the filament, ReRAM devices can be classified as one of two main types: electrochemical metallization (ECM) or valence change mechanism (VCM).

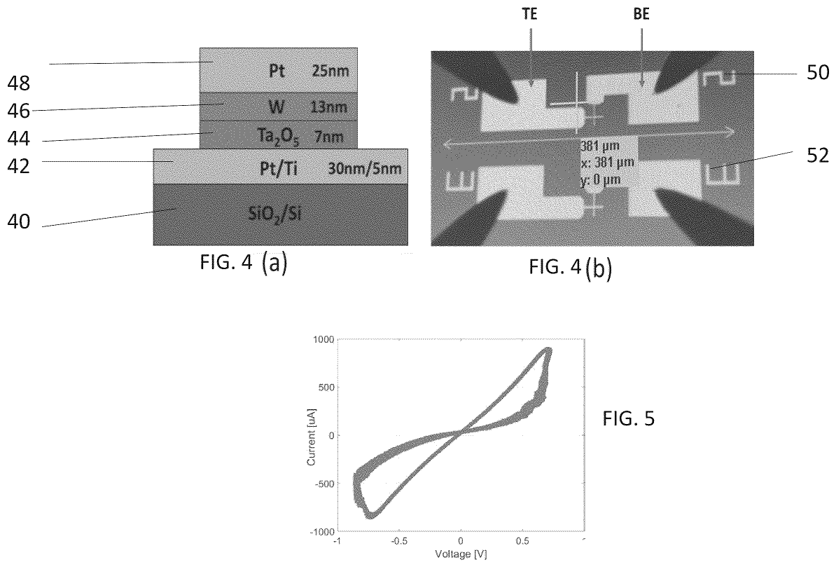

We choose a valence-change mechanism (VCM) memristor for the present embodiments due to the abrupt SET transition. Abrupt transitioning to a lower resistance may allow an AGC mechanism according to the present embodiments to be activated almost instantly. Reference is now made to FIG. 4(A) which shows a cross-sectional diagram of the layers of a VCM memristor. A base of silicon dioxide on silicon 40 underlays a platinum or titanium layer 42, which in turn underlays a tantalum oxide layer 44, and which in turn underlay tungsten 46 and platinum 48. FIG. 4(b) shows a microscope image of a pair 50, 52 of the VCM memristors. The VCM memristor was tested and characterized on a probe station evaluating its parameter values, including R_{off}, Rₒₙ, V_{SET}, and V_{RESET}. Additionally, the expected cycle-to-cycle variance of these parameters was measured.

The measured I-V curve of the device is shown in FIG. 5. The curve shows 200 switching cycles for the VCM memristor. The memristor's

$$\frac{{R}_{off}}{{R}_{on}}$$

ratio is approximately 100 on average, sufficiently high to extend the dynamic range of the TIA by 40 dB. When a positive voltage higher than a certain threshold (the SET threshold) is applied across the device, the memristor undergoes a SET event and switches from an average HRS of (15Ω) to an average LRS of (120Ω). Once a negative voltage higher than the reset threshold is applied, the memristor undergoes a RESET event and switches back to an HRS.

Based on the experimental results, the memristor was modeled in SPICE using a binarized state switching model. The model easily configures the memristor's R_{off} and Rₒₙ values, switching speed, and threshold voltages. The model also exhibits abrupt SET transition. The disadvantage of this model is its lower accuracy in modeling the RESET transition.

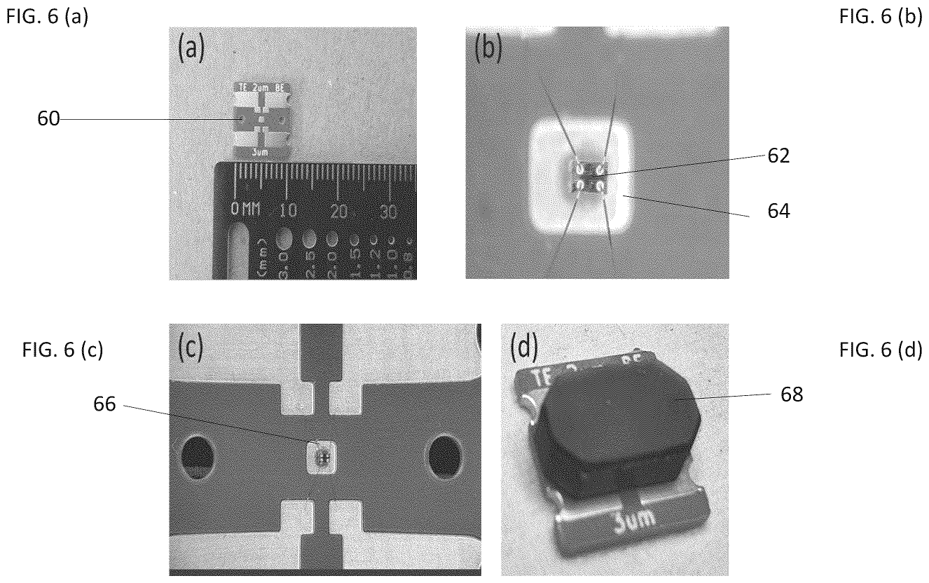

Reference is now made to FIGS. 6(a)-6(d) which illustrate a fabricated VCM memristor being integrated with the TIA circuitry by mounting it on a printed card board (PCB) carrier. The VCM memristor's wafer was diced into pairs of dies and then glued to a PCB carrier. Following this, it was wired to the PCB pads, under a protective enclosure. Specifically, FIG. 6. (a) shows a bare PCB carrier 60. FIG. 6(b) shows a memristor 62 attached with glue (silver epoxy adhesive) to the PCB metal pad 64. FIG. 6(c) shows memristor wiring 66 to the PCB, and FIG. 6(d) shows a plastic enclosure 68 protecting the bonded memristor.

### TIA

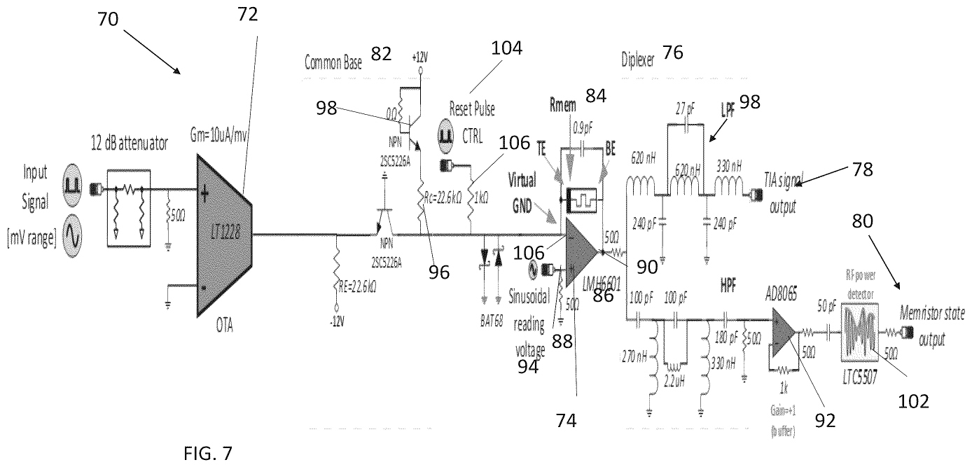

FIG. 7 shows a more specific schematic 70 of a circuit according to the present embodiments. We replaced the photo-diode with an operational transconductance amplifier (OTA) 72 to validate the proposed design. The OTA (also known as a Gₘ stage) converts voltage input signals into current signals and drives the input current signal into the TIA stage 74.

More particularly, FIG. 7 shows a schematic of the proposed memristor-based transimpedance AGC amplifier circuit. The OTA stage 72 output current flows through the common-base and the TIA stage 74. An output diplexer 76 after the TIA 74 splits the signal to two paths, a low pass path 78 for the output signal and a high pass path 80 for a sinusoidal reading signal, which will be discussed in greater detail below.

The circuit is constructed as follows: The input voltage arrives from the test equipment, and an attenuator limits its amplitude. Since the OTA 72 has a high transconductance gain, the input voltage has to be limited (otherwise, the OTA would be saturated easily). The OTA stage (based on the LT1228 amplifier) 72 converts the input voltage signals into current signals that flow (from the left side of the circuit to the right side) to the TIA stage 74. Since high currents can damage the memristor, the maximum current is limited to a compliance current of 500 μA using a common-base stage 82. The common-base stage 82 acts as a current buffer (having a unity current gain) for a current lower than the compliance current. The current arriving at the TIA stage 74 flows through the memristor 84 and is converted into voltage, using the LMH6601 86 as the operational amplifier for the TIA stage. Since the voltage at the operational amplifier non-inverting input 88 is at virtual ground, the output voltage at the TIA output 90 is negative. The TIA output is

$$V {TIA}_{out} = - {I}_{in} \cdot Rmem . \qquad ( 6 )$$

The TIA output 90 is connected to Hi/Lo output diplexer 76. The diplexer 76 separates the amplified signal output into low-pass filter branch 78 and a high-frequency sinusoidal measurement signal that indicates the memristor's state and goes through branch 80. The high-pass filter branch 80 includes an R_{F} power detector 92. The R_{F} detector 92 converts the high-frequency sinusoidal signal to a DC voltage according to the amplitude of this signal.

The TIA 74 of the present embodiments works as follows. The memristor 84 is initiated at a high resistive state; therefore, the TIA 74 intially has a high gain as required for the system bandwidth and sensitivity. As long as the input current is of relatively low magnitude, the TIA 74 operates as a regular TIA. When the input current increases and approaches the maximum current the TIA 74 can amplify before it saturates, the circuit outputs a sufficiently high voltage to SET the memristor 84. Since the top electrode TE of the memristor is held at virtual ground, the bottom electrode BE's voltage needs to be negative with an absolute value higher than the SET voltage of the memristor to switch the memristor 84 into a low resistance state. Once the memristor 84 switches, the TIA 74 gain is reduced. As long as the TIA gain is reduced, it can withstand high current levels without being saturated. Incorporating the memristor 84 into the TIA's feedback network allows the circuit to gain AGC capability and increases the dynamic range by the memristor's

$$\frac{{R}_{off}}{{R}_{on}}$$

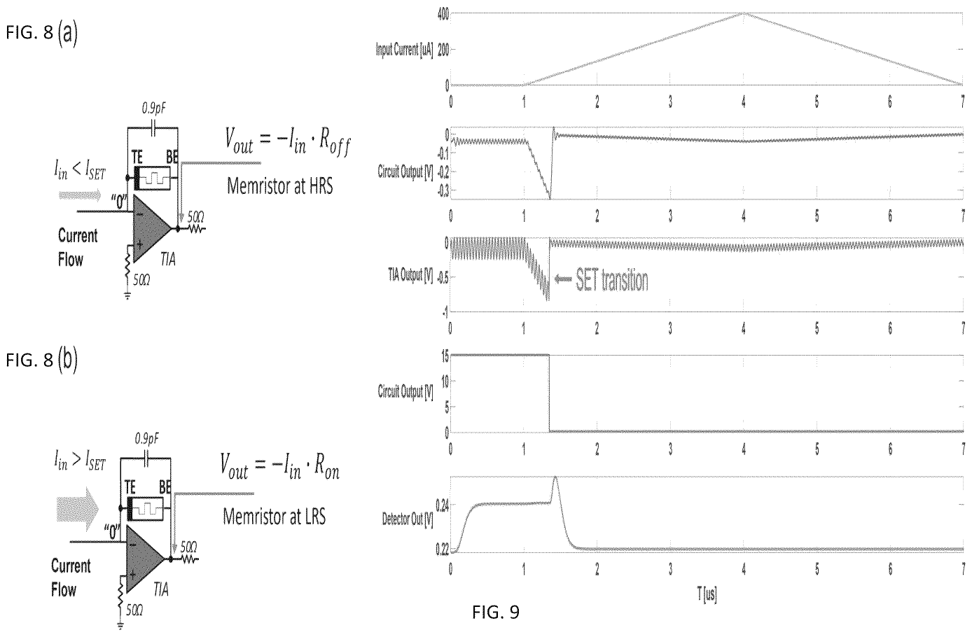

ratio. Reference is now made to FIGS. 8a and 8b which illustrate the TIA operation including the state transition. In FIG. 8 (a) the memristor is initiated at HRS and TIA has high sensitivity for low input signal acquisition. In FIG. 8(b) the memristor switches to LRS once the input current is higher than the threshold current. High input currents do not saturate the TIA in this state.

The memristor state may be monitored to track the TIA gain. Tracking the TIA gain may provide the correct input current levels to allow the memristor to be switched. The monitoring may be performed without affecting the memristor state. We add reading circuits to monitor the memristor resistance state, as discussed above in respect of FIG. 7. The non-inverting input of the operational amplifier is connected to a sinusoidal source 94. The operational amplifier 86 amplifies the sine wave via the non-inverting configuration amplification. The amplification gain for the reading sine signal is

$$Reading signal gain = 1 + {R}_{mem} / {R}_{c} \qquad ( 7 )$$

where R_{C} is the resistor 96 connected to the NPN transistor 98 collector (see FIG. 7). Therefore, the reading sine waveform is amplified according to the memristor resistance. This amplified waveform is combined with the TIA output signal.

To separate these two signals, Hi/Lo output diplexer 76 is deployed. The reading sine signal frequency is selected to be higher than the TIA bandwidth (two to three times higher). The TIA output is filtered by a low pass filter 98 to remove the sine wave, while the amplified sine wave propagates through high pass filter branch 80 to be filtered through high pass filter 100 and is transferred to an R_{F} power detector 102, for which LTC5507 is used. The R_{F} power detector output is a DC signal proportional to its input voltage's logarithm. The memristor 84 resistance state is deduced by sampling and monitoring the R_{F} power detector output level. Higher R_{F} power detector output is translated into higher memristor resistance.

Once the memristor switches to an LRS (due to high input current signal), the TIA sensitivity is reduced. The memristor must be reset back to a HRS to allow the TIA to recover its sensitivity. A RESET pulse is applied to the memristor by the reset pulse control 104 (see FIG. 7). The external RESET signal is connected to the amplifier's inverting input through a 1kΩ resistor. The RESET signal is amplified by the operational amplifier of the TIA 74 where it is connected to the inverting configuration gain 106. The RESET signal amplification gain is, therefore,

$$RESET signal gain = ( - {R}_{mem} ) / 1 k \qquad ( 8 )$$

A negative RESET signal may subsequently be applied to switch the memristor back to an HRS.

### Simulation Results

We used LTspice to simulate the complete circuit. FIG. 9 shows the simulation results. The memristor was initiated to an HRS of 15k Ω(its LRS was configured to 120Ω). These values correspond to the average values measured for the VCM memristor. The input signal for the TIA was a triangular current signal reaching 400 μA. The simulation results show the TIA output and the circuit output response to the TIA's input current signal. The output is half the voltage of the TIA output due to the 50Ω matching termination. The simulation's waveform shows how the TIA output becomes more negative as the input current rises, given the TIA is an inverting amplifier, and that continues until the set transition occurs. After the set transition, the memristor switches to an LRS and the TIA gain drops, which prevents saturation even though the current signal further increases.

The TIA gain can be extracted from the slope of the circuit output waveform. The simulation waveform of the TIA output has a sine wave imposed on it due to the amplified reading signal that also appears at the TIA output. This signal is attenuated by the diplexer low pass filter branch, which is seen in the circuit output waveform. The bottom waveform shows the RF power detector output whose value corresponds to the memristance state, it being noted that a higher voltage value means the memristance has a higher value.

There are several limitations to our simulations. First, the memristor parameters (like HRS, LRS, and threshold voltages) vary from cycle to cycle, and our basic simulations used only their average value. Second, measuring directly the high-speed current signals at the TIA input is almost impossible. Therefore, we measured in our experiments the input voltages of the OTA, while in simulations, we show the TIA's input current signal directly.

### Circuit Evaluation

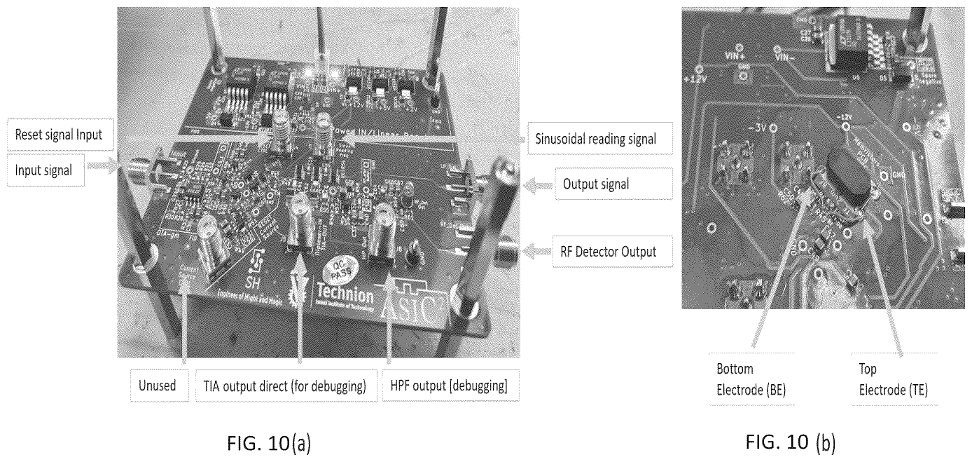

A PCB was used to implement the proposed circuit, which includes the OTA, TIA stage, and circuits for monitoring and resetting the memristor. The memristor's carrier board (FIG. 6) was soldered to the PCB adjacent to the TIA amplifier. The evaluation board is shown in FIGS. 10(a) top view and 10(b) bottom view.

Although the presently discussed embodiment was built from discrete components on a PCB board, it will be clear that in practice an integrated circuit implementation is likely to be used. The present embodiment shows a TIA configuration based on a discrete amplifier and a specific model of operational amplifier. However a commercial implementation may use a fully integrated form (IC). Although the idea was validated in a discrete form as per FIG. 10 the present simulations extend to integrated circuit form.

It is noted that when the TIA is in IC form, there is less of a distinction as to whether the input signal is connected to the inverting input of the TIA, since there are many more IC implementations of TIA circuits and the mention of connection to an inverting input is to be understood accordingly.

In an integrated circuit implementation, the memristor may be made available as a replacement for the gain-setting resistor to achieve the increase of the dynamic range.

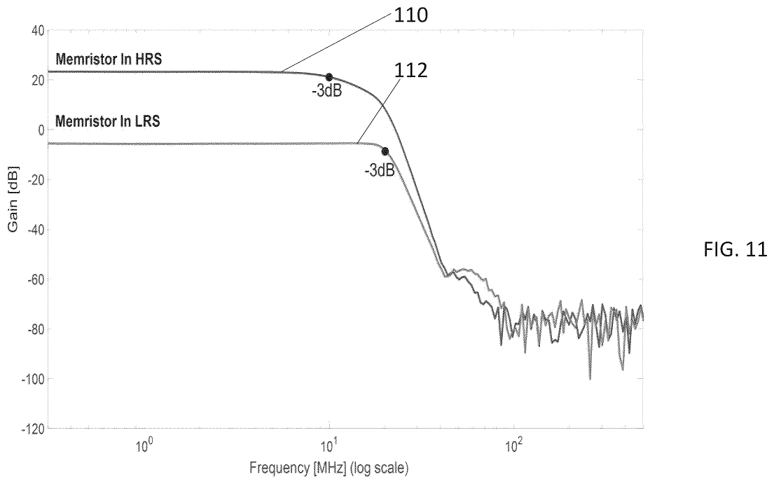

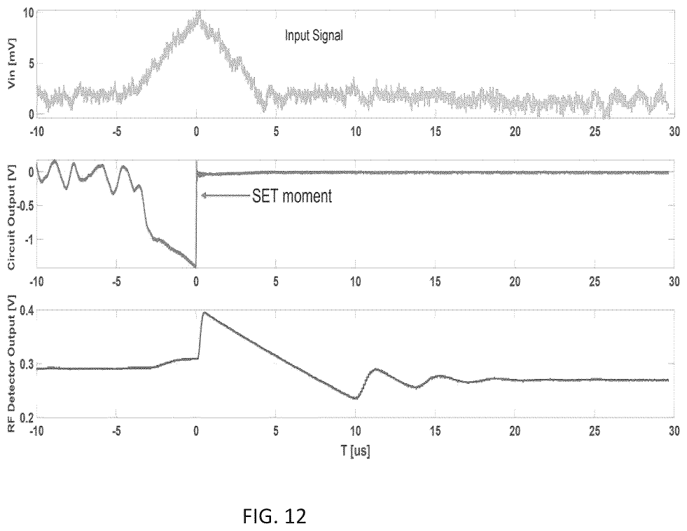

Reference is now made to FIG. 11 which shows the measured gain against frequency for the TIA per the two states of the memristor 84. The board was connected to a vector network analyzer (VNA) to measure the frequency response when the memristor 84 is in HRS 110 and LRS 112 states respectively. The bandwidth, although limited by the OTA 72 and the low pass filter 98, is higher when the memristor 84 is in the LRS. This behavior is similar to that of a TIA that has a low feedback resistor value, as explained by equation (2) above. FIG. 12 shows the switching of the memristor to LRS and the reduction of the TIA gain. The memristor was initiated in the HRS state, and the input signal was configured to be a triangular wave. The change in the resistance is also observed in the R_{F} detector output level waveform, in that the amplitude was reduced after some settling time. The SET transition m ay happen very fast, that is on a nano-second scale, and therefore, allows the TIA gain to decrease immediately when large signals appear. The switching of the memristor 84 between its initial HRS to an LRS enables the dynamic range to be increased by the memristor's

$$\frac{{R}_{off}}{{R}_{on}}$$

ratio. The memristor used for evaluation has a

$$\frac{{R}_{off}}{{R}_{on}}$$

ratio of approximately 100 and, therefore, enabled the TIA dynamic range to be increased by 40 dB. Using memristors with a higher

$$\frac{{R}_{off}}{{R}_{on}}$$

ratio would further increase the dynamic range.

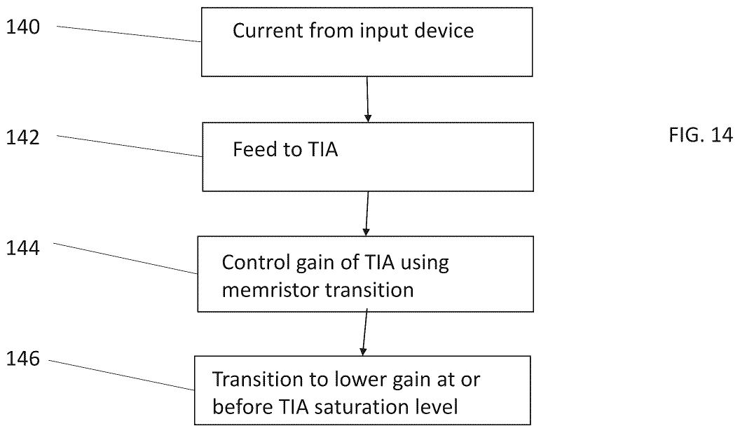

Reference is now made to FIG. 14, which is a simplified flow chart illustrating a process for signal acquisition according to the present embodiments.

The current containing the signal to be acquired is obtained from the input device say an 30 optical device—140. The current is within a current range of the input device, which may be quite large and beyond the dynamic range of the transimpedance amplifier. In 142, the current is fed to the transimpedance amplifier and amplified.

In 144, the gain of the transimpedance amplifier is controlled by connecting a memristor component across a feedback path of the transimpedance amplifier. The memristor component is selected to have a set transition at or close to the saturation level of the transimpedance amplifier, so that as saturation is reached, the gain of the transimpedance amplifier is lowered −146. Thus the dynamic range of the transimpedance amplifier is enlarged to better match the current range of the input device.

A limitation observed during the evaluation was the cycle-to-cycle variations of the memristor. The SET threshold voltage exhibited approximately 20% cycle-to-cycle variation, while the R_{off} had a very high spread primarily due to the parameters of the RESET pulse used. The memristor that is used for this application may be modified to reduce its R_{off} variance. One method to achieve low cycle-to-cycle variation is incorporating nanocrystals into the memristor oxide. Using circuit-level solutions may also improve immunity to cycle-to-cycle variations. For example, a better feedback network can be designed to reduce the effect of R_{off} variance on the TIA performance. The memristor can be connected in parallel to another fixed-value resistor. As long as the memristor's R_{off} is larger than the fixed resistor value, the variance of the R_{off} would have a minor effect, as the fixed resistor would define the TIA's gain. Only once the memristor switches to an LRS, it would significantly lower the TIA gain and prevent saturation of the amplifier.

Our solution requires monitoring of the memristor state to reset it with an appropriate signal when the TIA needs to be restored to its high gain configuration for high sensitivity.

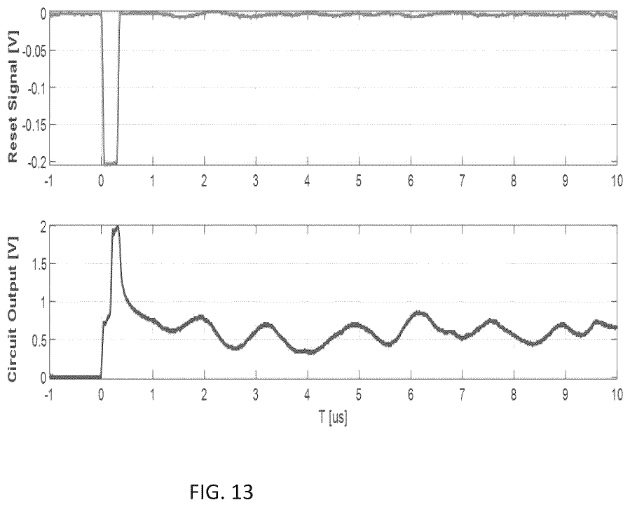

FIG. 13 shows the RESET signal. Before the pulse is activated, the memristor is in an LRS state, and the TIA gain is low, as evident by the low output voltage. After the successful RESET, the memristor switches back to its initial resistance, and the TIA gain is substantially increased, as evident by the noisy output voltage caused by environmental noise greatly amplified by the amplifier.

There is an issue that is related to the RESET signals. Since the required RESET signal length varies from cycle to cycle and is affected by the specific Rₒₙ, it was impossible to inject a RESET signal with the exact duration to cause the RESET transition. The RESET signal duration was always longer and continued even after the memristor switched to an HRS. Since the RESET signal appears at the TIA output after amplification that depends on the memristor resistance state as in (8), once the memristor switches to HRS, the RESET signal is tremendously amplified. It causes the TIA to be saturated after a RESET signal is activated. The issue continued even after the memristor switched to an HRS. Since the RESET signal appears at the TIA output after amplification that depends on the memristor resistance state as in equation (8), once the memristor switches to HRS, the RESET signal is tremendously amplified. It causes the TIA to be saturated after a RESET signal is activated. The issue may be addressed by the use of volatile memristors instead of performing an explicit RESET operation. Volatile memristors are able to self-reset and thus the issue is obviated. In the case of volatile memristors, there is no need for the reading circuit or diplexer, or for that matter for the sinusoidal source.

A particular example of a volatile memristor device, is a Mott device. The Mott device uses the Mott transition, which is in general a transition between a metallic state and an insulative state, and the Mott transition device may be connected across the TIA feedback path as with any other kind of memristor device.

High dynamic rang is a highly desirable parameter in TIA circuits. Today's traditional high dynamic range circuits are highly complex and have an inherent tradeoff between bandwidth, dynamic range, and linearity. The memristor-based TIA of the present embodiments demonstrates that using the memristor as the feedback element of a TIA amplifier makes it possible to have an AGC mechanism without any active feedback circuitry that monitors the TIA output and adjusts the gain accordingly, as many traditional solutions do. The present disclosure demonstrates the solution on a PCB and shows that the dynamic range of the TIA is extended in line with the memristor's R_{off}/Rₒₙ ratio.

### General

The terms “comprises”, “comprising”, “includes”, “including”, “having” and their conjugates mean “including but not limited to”.

The term “consisting of” means “including and limited to”.

As used herein, the singular form “a”, “an” and “the” include plural references unless the context clearly dictates otherwise.

It is appreciated that certain features of the invention, which are, for clarity, described in the context of separate embodiments, may also be provided in combination in a single embodiment and the present description is to be construed as if such embodiments are explicitly set forth herein. Conversely, various features of the invention, which are, for brevity, described in the context of a single embodiment, may also be provided separately or in any suitable subcombination or may be suitable as a modification for any other described embodiment of the invention and the present description is to be construed as if such separate embodiments, subcombinations and modified embodiments are explicitly set forth herein. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

It is the intent of the applicant(s) that all publications, patents and patent applications referred to in this specification are to be incorporated in their entirety by reference into the specification, as if each individual publication, patent or patent application was specifically and individually noted when referenced that it is to be incorporated herein by reference. In addition, citation or identification of any reference in this application shall not be construed as an admission that such reference is available as prior art to the present invention. To the extent that section headings are used, they should not be construed as necessarily limiting. In addition, any priority document(s) of this application is/are hereby incorporated herein by reference in its/their entirety.

1. A device for signal acquisition, comprising:
a transimpedance amplifier having at least one input, the at least one input being connected to receive a current from an input device;
an output of said transimpedance amplifier configured to supply an output voltage in response to said current; and
a memristor component connected in a feedback path of said transimpedance amplifier, said feedback path being between said output and said at least one input, the memristor component being configured to transition between a high resistive state and a low resistive state depending on a voltage difference across said memristor component, thereby to reduce a gain of said transimpedance amplifier following an increase in said current, thereby to increase a dynamic range of said transimpedance amplifier.

2. The device of claim 1, wherein said memristor component is a resistive random access memory (ReRAM) component.

3. The device of claim 2, wherein said memristor component is a valence change mechanism (VCM) ReRAM device.

4. The device of claim 1, wherein said memristor component is a volatile memristor, for example a Mott volatile memristor device.

5. The device of anyone of claim 1, wherein said dynamic range is configured to maintain responsiveness of said transimpedance amplifier to an expected current range of said input device.

6. The device of claim 5, wherein said memristor component has a predetermined
$$\frac{{R}_{off}}{{R}_{on}}$$
ratio and said bandwidth is increased by said predetermined
$$\frac{{R}_{off}}{{R}_{on}}$$
ratio.

7. The device of claim 1, wherein said memristor component is selected for a set transition in an order of magnitude of nanoseconds.

8. The device of claim 1, comprising a measurement component for measuring said output voltage, and using said measurement to supply a reset signal to said memristor component.

9. The device of claim 8, comprising a diplexer connected to split said output voltage into a first signal path indicative of said input current and a second signal path indicative of a need to reset said memristor component, said measurement device being connected to said second signal path.

10. The device of claim 9, wherein said at least one input of said transimpedance amplifier comprises an inverting input and a non-inverting input, said non-inverting input being connected to a sinusoidal source, to be amplified by said transimpedance amplifier to indicate gain, the first signal path being low pass filtered and said second signal path being high pass filtered.

11. The device of claim 1, implemented as an integrated circuit.

12. A method of signal acquisition from an input device using a transimpedance amplifier comprising:
obtaining a current from the input device, said current being within a current range of said input device;
amplifying said current using said transimpedance amplifier;
controlling a gain of said transimpedance amplifier by connecting a memristor component across a feedback path of said transimpedance amplifier, the memristor component selected to have a set transition close to a saturation level of said transimpedance amplifier, thereby to decrease a gain of said transimpedance amplifier prior to said current reaching said saturation level and thereby to increase a dynamic range of said transimpedance amplifier to better match said current range of said input device.

13. The method of claim 12, wherein said memristor component is a resistive random access memory (ReRAM) component.

14. The method of claim 13, wherein said memristor component is a valence change mechanism (VCM) ReRAM device.

15. The method of claim 12, wherein said memristor component is a volatile memristor, for example a Mott device.

16. The method of claim 12, wherein said memristor component has a predetermined
$$\frac{{R}_{off}}{{R}_{on}}$$
ratio and said bandwidth is increased by said predetermined
$$\frac{{R}_{off}}{{R}_{on}}$$
ratio.

17. The method of claim 12, wherein said memristor component is selected for a set transition in an order of magnitude of nanoseconds.

18. The method of claim 12, comprising measuring said output voltage, and using said measurement to supply a reset signal to said memristor component.

19. The method of claim 18, comprising splitting said output voltage into a first signal path indicative of said input current and a second signal path indicative of a need to reset said memristor component, said measuring being at said second signal path.

20. The method of claim 19, wherein said transimpedance amplifier comprises an inverting input and a non-inverting input, said inverting input being connected to receive said current, and said non-inverting input being connected to a sinusoidal source, the method comprising amplifying said sinusoidal source at said transimpedance amplifier to indicate gain, the first signal path being low pass filtered and said second signal path being high pass filtered.

21. The method of claim 12, wherein said input device is an optical input device and said device or method is for optical signal acquisition.
